(19) United States
(12) Patent Application Publication
(10) Pub. No.: US 2002/0181221 A1
(43) Pub. Date: Dec. 5, 2002

(54) Magnetic actuated fuse indicator

(76) Inventors: Karsten Ries, Frederiksberg (DK); Peter Damgaard, Albertslund (DK); Ole Gortz, Nykobing Sj (DK)

Correspondence Address: John S. Beulick, Armstrong Teasdale LLP, One Metropolitan Sq., Suite 2600, St. Louis, MO, 63102, US

(21) Appl. No.: 10/156,497

(22) Filed: May 28, 2002

Related U.S. Application Data
(60) Provisional application No. 60/294,078, filed on May 29, 2001.

(51) Int. Cl. H05K 7/00

(52) U.S. Cl. 361/837

(57) ABSTRACT

A fuse state indicator includes a housing, first and second fuse terminals extending from said housing, an actuator assembly disposed within said housing, and a magnetically actuated contact assembly disposed within said housing is provided. The contact assembly is responsive to the actuator assembly.

### CROSS REFERENCE TO RELATED APPLICATIONS

This application claims the benefit of U.S. Provisional Application Serial No. 60/294,078 filed May 29, 2001.

### BACKGROUND OF THE INVENTION

This invention relates generally to fuse state indicators, and, more particularly, to externally mounted fuse indicators.

Fuses are widely used overcurrent and short circuit protection devices for protecting electrical components and subsystems from damaging fault currents. Fuses typically include a fusible link extending in series with electrical conductors, or contacts, for connection to a circuit. When current flowing through the fuse exceeds a predetermined limit, the fusible link melts, thereby opening the fuse and isolating downstream electrical components by preventing current from flowing through the fuse contacts.

In some applications, and particularly in large electrical systems employing many fuses, fuse state indicators are employed to facilitate identification of an opened fuse or opened fuses. For this purpose, external fuse state indicators are sometimes used that are mounted to the fuses in electrical connection with the fuse terminals. Typically, the external fuse state indicators are mechanically actuated and include a thin fuse wire connected in parallel with the monitored fuse and restraining a spring loaded actuator. When the fusible link in the monitored fuse opens, current is directed to the thin fuse wire of the fuse state indicator, and when the thin fuse wire of the fuse state indicator opens, the actuator is released and displaced by a spring. The displacement of the actuator provides visual indication of the opened fuse and/or the displacement triggers remote fuse identification by tripping one or more microswitches coupled to external circuitry.

Mechanically actuated fuse state indicators of this type, however, are problematic in certain applications, such as fuse applications in dirty, hot or humid environments. These environments can oxidize or corrode the electrical contacts of the indicator and prevent proper operation of the indicator by producing false open fuse signals, especially when the monitored fuse endures for years or decades before opening. Moreover, microswitches associated with these indicators increase material costs, complicate assembly of the indicators, and undesirably increase the package size of the assembly

### BRIEF DESCRIPTION OF THE INVENTION

In one aspect, a fuse state indicator comprising a housing, first and second fuse terminals extending from said housing, an actuator assembly disposed within said housing, and a magnetically actuated contact assembly disposed within said housing is provided. The contact assembly is responsive to said actuator assembly.

In another aspect a fuse state indicator is provided. The indicator comprises a housing, first and second fuse terminals extending from said housing, a fuse wire extending between said first and second fuse terminals, an actuator arm situated within said housing and coupled to said fuse wire, a magnet element in abutting relationship with said actuator arm, a resilient element biasing said magnet element against said actuator arm, first and second contact terminals situated within said housing, and a magnetically actuated contact extending between said first and second contact terminals and responsive to a position of said magnet element.

In another aspect, an external fuse state indicator for attachment to a fuse is provided. The indicator comprises a housing, a fuse wire located within said housing and establishing an electrical connection to the fuse, first and second contact terminals located within said housing, a contact extending within said housing and configured to complete an electrical connection through said first and second contact terminals, and a permanent magnet disposed in said housing in a first position in spaced apart relationship from said contact. The magnet is biased to a second position in spaced apart relationship from said contact when said fuse wire operates, and the second position of said magnet effects a change in orientation of said contact.

In still another aspect, a fuse system is provided. The system comprises a fuse comprising a fuse body and first and second conductive elements coupled to said body, and a magnetically actuated fuse state indicator externally coupled to said body in electrical contact with said conductive elements.

### BRIEF DESCRIPTION OF THE DRAWINGS

FIG. 1 is a perspective assembly view of a magnetically actuated fuse state indicator.

FIG. 2 is a perspective assembled view of the fuse state indicator shown in FIG. 1.

FIG. 3 is a perspective view of the fuse state indicator shown in FIGS. 1 and 2 attached to a fuse.

FIG. 4 is an elevational view of a second embodiment of a fuse state indicator coupled to a fuse.

FIG. 5 is a magnified view of a portion of FIG. 4.

FIG. 6 is an elevational view of a third embodiment of a fuse state indicator coupled to a fuse.

FIG. 7 is a magnified view of a portion of FIG. 6.

### DETAILED DESCRIPTION OF THE INVENTION

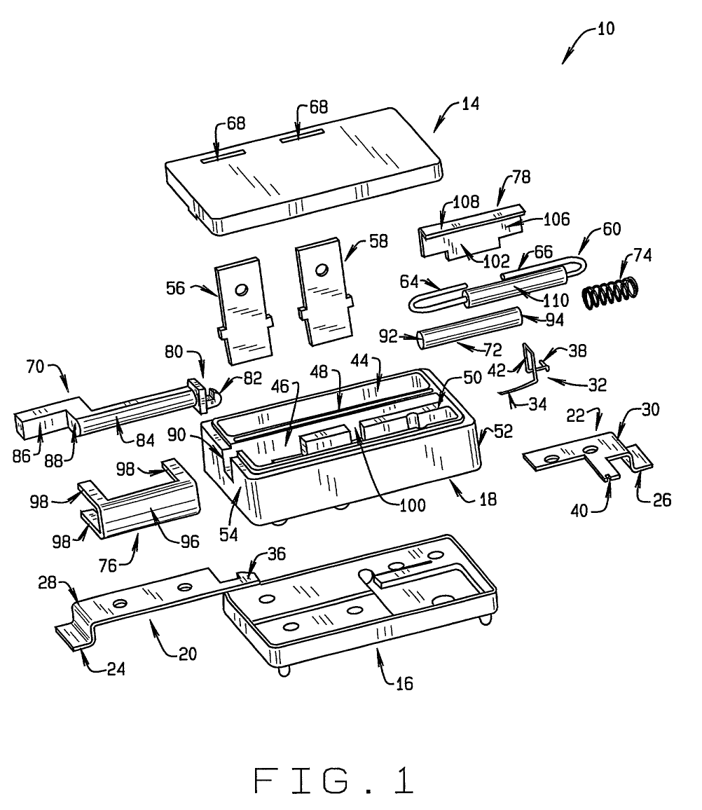

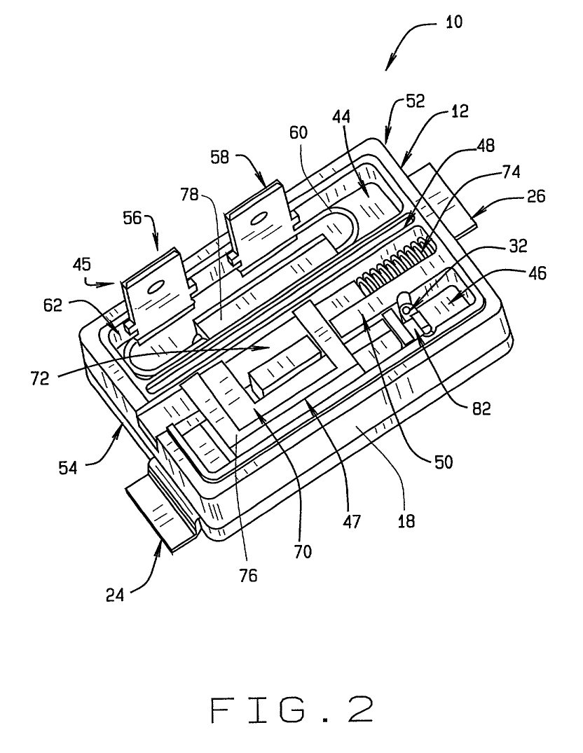

FIGS. 1 and 2 are an assembly and assembled view, respectively, of a fuse state indicator 10 that provides reliable fuse state indication in a wide variety of operating environments.

Fuse state indicator 10 includes an insulative body including opposite top and bottom covers 14, 16, respectively, and an actuator housing 18 in between. In one embodiment, covers 14, 16 and actuator housing 18 are fabricated from known plastic or thermoplastic materials capable of withstanding heat generated in operation of fuse state indicator 10, and covers 14, 16 are sealingly engaged to actuator housing 18 according to known methods and techniques to form a hermetic enclosure for actuator components, described in detail below. Thus, fuse state indicator 10 may be employed in, for example, dirty and humid operating environments while protecting actuator components from corrosion and oxidation that may impair operation of fuse state indicator 10.

Fuse state indicator 10 further includes first and second fuse terminals 20, 22 extending between bottom cover 16 and actuator housing 18. Each terminal 20, 22 includes mounting apertures therethrough for fastening to lower cover 16 with complementary mounting apertures and known fasteners, such as ultrasonic welding, conventional screws, and nuts extending through the mounting apertures of terminals 20, 22 and lower cover 16. Each terminal 20, 22 further includes L-shaped coupling portions 24, 26 extending from respective distal ends 28, 30 of terminals 20, 22. Coupling portions 24, 26 establish electrical connection with respective terminals of a monitored fuse (not shown in FIG. 1) when fuse state indicator 10 is in use. A fuse wire 32 establishes an electrical connection through fuse state indicator terminals 20, 22 and therefore establishes an electrical path through fuse state indicator 10 in parallel with the fusible link or fuse link assembly of the monitored fuse.

In one embodiment, fuse wire 32 includes a first straight portion 34 for connection to a proximal end 36 of terminal 20, a second straight portion 38 for connection to a proximal end 40 of terminal 22, and a loop portion 42 extending between straight portions 34 and 38. In alternative embodiments, other configurations or shapes of fuse wire 32 are employed to accomplish the same or similar functional purposes of fuse wire 32 as set forth below.

In a further embodiment, fuse wire 32 is fabricated from wolfram, has a thickness of about 0.1 mm, and a length of about 20 mm. Wolfram was selected primarily for its relatively high temperature coefficient and melting point that achieves satisfactory operation of fuse state indicator 10 without excessive heat generation that may damage covers 14, 16 and actuator housing 18 when fuse state indicator 10 operates. In a particular embodiment, this configuration of fuse wire 32 causes fuse wire 32 to melt and open at high voltages (e.g., greater than about 10V), while generating sufficient operating temperatures to also cause melting at lower voltages (e.g., less than about 10V) that may be encountered when monitored fuses are connected in parallel with one another. Fuse indicator 10 in such instances provides early warning before electrical system failure due to excessive voltage drop over fused circuits connected in parallel.

It is contemplated that fuse wire 32 may be differently dimensioned in alternative embodiments to achieve other performance parameters beyond those described thus far, and furthermore that other known materials employed in the fabrication of high resistance wire may be used for fabricating fuse wire 32, including but not limited to wolfram alloys, chrome and nickel alloys, and other materials appreciated by those in the art.

Actuator housing 18 includes a sensor receptacle or cavity 44 for housing a contact assembly 45 (shown in FIG. 2), and an actuator receptacle or cavity 46 for housing an actuator assembly 47 (shown in FIG. 2). Sensor receptacle 44 and actuator receptacle 46 are separated from one another by a barrier wall 48, and actuator receptacle 46 includes a partition 50 extending partially between opposite longitudinal ends 52, 54 of actuator housing 18.

Contact assembly 45 includes a pair of sensor contact terminals 56, 58 and a reed contact 60 for establishing an electrical connection between sensor terminals 56, 58. As shown in FIG. 2, terminals 56, 58 are situated in an upstanding fashion against a rear wall 62 of sensor receptacle 44, and opposite ends 64, 66 (shown in FIG. 1) of reed contact 60 are in electrical contact with respective contact terminals 56, 58. Thus, when contact terminals 56, 58 are connected to external circuitry, reed contact 60 completes the electrical circuit between contact terminals 56, 58, thereby facilitating remote fuse state indication that the monitored fuse has not opened, or in other words, that the fuse has not operated when reed contact 60 remains in a closed contact position as illustrated in FIG. 2. Terminal openings 68 are provided in upper cover 14 so that terminals 56, 58 protrude through an outer surface of upper cover 14 when cover 14 is attached to actuator housing 18.

Actuator assembly 47 includes an actuator arm 70, a permanent magnet 72, a bias member 74, and shielding magnetic shunts 76, 78. Actuator arm 70 includes an actuator end 80 including a hook 82 for receiving loop portion 42 of fuse wire 32, a first longitudinal portion 84 extending from actuator end 80, and a second longitudinal indicator portion 86 extending from first longitudinal portion 84. First and second longitudinal portions 84, 86 extend generally parallel to one another and are joined by a connecting member 88 extending substantially perpendicular to longitudinal portions 84, 86. Actuator arm 70 is disposed within actuator receptacle 46 such that actuator end 80 and first longitudinal portion 84 are disposed on one side of receptacle partition 50, and second longitudinal portion 86 is disposed on the other side of receptacle partition 50. Second longitudinal portion 86 is disposed adjacent to and axially aligned with a notch or opening 90 in actuator housing lateral sidewall 54 so that when fuse state indicator 10 is operated, actuator arm second longitudinal portion 86 extends through notch 90 to provide visual indication of the opened monitored fuse.

Magnet element 72 is disposed in actuator receptacle 46 on an opposite side of partition 50 than actuator aim first longitudinal portion 84. In one embodiment, magnet element 72 is a permanent magnet, although in alternative embodiments it is recognized that other magnetic and/or magnetizable materials may be employed.

In an illustrative embodiment, a first end 92 (shown in FIG. 1) of magnet element 72 abuts actuator arm connecting member 88 (shown in FIG. 1), and a second end 94 (shown in FIG. 1) abuts a resilient bias member 74 that, in turn, abuts lateral sidewall 52 of actuator housing 18. In one embodiment, bias member 74 is a helical compression spring. In alternative embodiments, other known bias members and mechanisms may be employed for achieving the fuse indicator operation described below.

To prevent electromagnetic interference from magnetic stray fields generated by adjacent conductors in high power multiphase electrical systems, magnetic shunts or shields 76 and 78 are provided. Shunt 76 includes a sleeve portion 96 that receives actuator arm first longitudinal portion 84, and a plurality of legs 98 extending from sleeve portion 96 across actuator receptacle 46 of actuator housing 18, and at least one leg 98 is received in a notch 100 in receptacle partition 50. Shunt 78 is situated in sensor receptacle 44 of actuator housing 18, and includes a tab 102 for engagement with a groove (not shown) in housing 18, a coplanar partition portion 106 extending from tab 102, and cover portion 108 extending substantially perpendicular to partition portion 106 and tab 102. Shunt 78 is located over reed contact 66, and more specifically, a contact tube 110 of reed contact 60, to form a two sided enclosure over contact tube 110 in conjunction with actuator arm barrier wall 48. While shunt 78 is believed to be advantageous for certain fuse applications, it is recognized that most, if not all, of the advantages of the instant invention may be achieved in other applications without utilizing shunt 78.

Once assembled, as shown in FIG. 2, fuse wire 32 completes an electrical connection through terminals 20 and 22 that may be coupled to fuse terminals (not shown) of the monitored fuse via coupling portions 24, 26. An electrical path through terminals 20, 22 and fuse wire 32 is therefore created that is in parallel with the fusible link or fuse link assembly of the monitored fuse. Fuse wire loop portion 42 is received in actuator end hook 82 of actuator arm 70, and maintains actuator arm 70 in a position within actuator receptacle 46 wherein second longitudinal portion 86 of actuator arm 70 is generally flush with an exterior surface of actuator housing lateral sidewall 54. As such, magnet element 72 that abuts actuator arm connecting member 88 compresses bias member 74 against actuator housing lateral sidewall 52.

The magnetic flux of magnet element 72 maintains reed contact 60 in the closed position wherein contact ends 64, 66 establish an electrical connection with terminals 56, 58. Because the electrical resistance of fuse wire 32 is much greater than the electrical resistance of the fusible link or fuse link assembly of the monitored fuse, only a very small portion of operating current of the fuse is experienced by fuse state indicator 10. When sensor contact terminals 56, 58 are connected to external circuitry, such as an alarm circuit, contact terminals 56, 58 complete the circuit through reed contact 66 and therefore provide remote fuse state indication that the monitored fuse is operable, i.e., has not opened. Local fuse state identification is provided by the position of second longitudinal portion 86 of actuator arm 80 generally within actuator receptacle 46 of actuator housing 18.

When the monitored fuse opens upon occurrence of a fault condition, all of the current is directed through fuse state indicator 10 because the parallel electrical path through the monitored fuse has been opened. When current flowing through terminals 20, 22 and through fuse wire 32 are sufficient to heat fuse wire 32 to its melting point, fuse wire 32 melts, disintegrates, evaporates, or otherwise opens and consequently can no longer restrain actuator arm 70 against the bias of bias member 74. Thus, once fuse wire 32 opens, actuator arm 70 and magnet element 72 are longitudinally displaced by bias member 74 and actuator arm second longitudinal portion 86 is extended through notch 90 in actuator housing lateral sidewall 54 to locally indicate the fuse state by the position of actuator arm second longitudinal portion 86 extending through sidewall 54 of actuator housing 12. Further, displacement of magnet 72 changes the magnetic flux experienced by reed contact 60 and causes reed contact 60 to open and break the electrical connection between contact terminals 56, 58, thereby facilitating remote fuse identification that the monitored fuse has opened when contact terminals 56, 58 are connected to external circuitry.

To prevent the magnetic flux of magnet element 72 from closing reed contact 66 and re-establishing an electrical connection through contact terminals 56, 58, shunt 76 is provided to absorb and carry the magnetic flux once magnet element 72 is displaced by bias member 74. Shunt 76 cancels magnet flux from magnet element 72 entering reed contact 60 when indicator 10 is activated. As such, proper operation of indicator 10 is not dependent upon relative positions of reed contact 60 and magnet element 72. Additionally, shunt 76 avoids electromagnetic interference from sources external to indicator 10.

Shunt 78 is provided in one embodiment around reed contact tube 110 to further reduce current induced stray magnetic fields from other electrical conductors in an electrical system from influencing or impairing operation of fuse state indicator 10. In an illustrative embodiment, shunt 78 is situated opposite magnet element 72 to minimize its influence on the near magnetic field of magnet element 72 while effectively avoiding external magnetic influences.

It is contemplated that with appropriate modification of actuator components, reed contact 60 could be configured in an alternative embodiment to be in a normally open position, as opposed to the normally closed position described above. That is, reed contact 60 may be manipulated to close and complete an electrical connection between contact terminals 56, 58 when the monitored fuse has opened, in contradistinction to the embodiment described above, without departing from the scope of the present invention. It is believed that such modification is within the purview of those in the art and could be accomplished without further explanation.

In still a further embodiment, another contact terminal could be provided in indicator 10 in addition to contact terminals 56, 58. In such an embodiment one of the terminals could be used as a neutral terminal such that, when employed with a reed contact, the indicator could be operated in both normally open and normally closed contact modes as determined by user preference and which of the contact terminals is connected to external circuitry.

To suppress arcing conditions when fuse state indicator 10 opens, an arc quenching medium, such as ceramic glue in one embodiment, is placed around fuse wire 32. In alternative embodiments, other known materials are employed that are capable of arc suppression and carrying heat from fuse wire 32 at low voltages.

Unlike conventional fuse state indicators, fuse state indicator 10 is electromagnetically actuated for local and remote fuse state indication in a compact, hermetic package for reliable operation in an economical package.

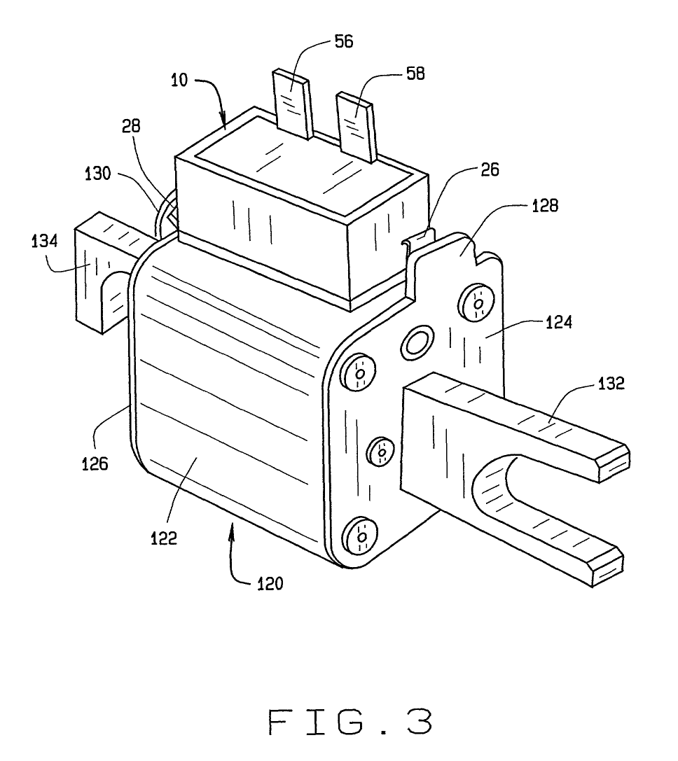

FIG. 3 is a perspective view of fuse state indicator 10 coupled to a fuse 120. While illustrated with a specific fuse 120, it is contemplated that fuse indicator 10 may be employed with a variety of differently configured fuses with appropriate modification that will be readily appreciated by those of skill in the art. Thus, fuse 120 as depicted and described herein is for illustrative purposes only and is not intended to limit the invention in any aspect.

Fuse 120 includes an insulative fuse body 122 and conductive elements 124, 126 coupled to respective opposite ends of fuse body 122 with known fasteners. As illustrated in FIG. 3, fuse body 122 has a generally square configuration and conductive elements 124, 126 are substantially square and complimentary in shape to fuse body 122. Each conductive element 124, 126 includes a respective tab projection 128, 130 extending above an outer surface of fuse body 122, and the outer perimeter of conductive elements 124, 126 are otherwise substantially flush with an outer surface of fuse body 122. Conductive elements 124, 126 in the illustrated embodiment are conductive end plates, and tab projections 128, 130 provide a conductive surface for connection of fuse indicator 10. Additionally, and as illustrated in FIG. 3, in an exemplary embodiment fuse 120 includes blade terminals 132, 134 for line and load-side connection to an electrical circuit (not shown). In alternative embodiments, other known connection schemes are provided in lieu of blade terminals 132, 134.

Internally, fuse 120 includes a fuse link or fusible assembly establishing an electrical circuit between conductive elements 124, 126 when fuse 120 is coupled to an energized circuit. In accordance with known fuses, the fuse link or fusible assembly is constructed to melt, disintegrate, fail, or otherwise open the electrical circuit through fuse 120 upon the occurrence of a predetermined current condition flowing through fuse 120.

Fuse indicator 10 is coupled to fuse conductive elements 128, 130 such that fuse indicator 10 is connected in parallel to the fuse link or fusible assembly of fuse 120. Specifically, fuse terminals 26, 28 are received in respective slots (not shown in FIG. 3) of tab projections 128, 130 of fuse conductive elements 124, 126. As such, a secondary electrical connection is established through indicator fuse wire 32 (shown in FIG. 1) for fuse state indication of the monitored fuse 120. Actuator arm 70 (shown in FIGS. 1 and 2) and contact terminals 56, 58 therefore provide local and remote fuse state indication as described above.

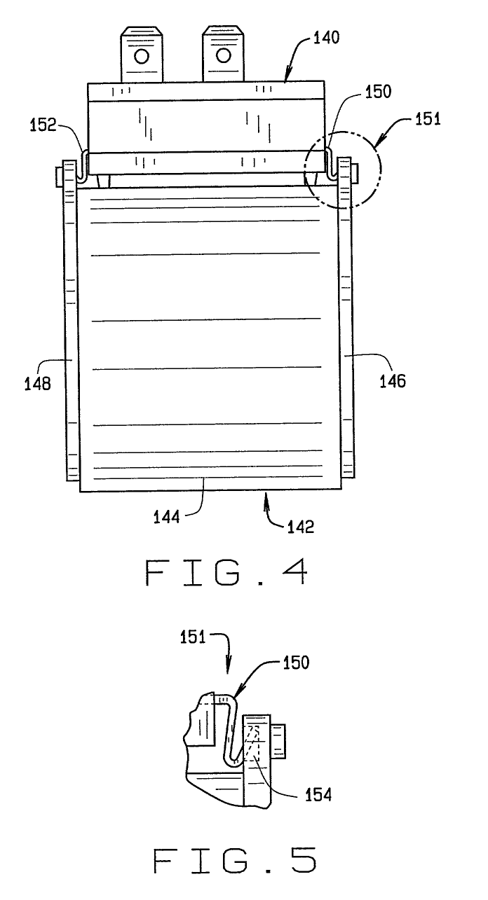

FIGS. 4 and 5 are an elevational view and a detail view of a second embodiment of a magnetic actuated fuse state indicator 140 coupled to a fuse 142. Fuse 142 includes a fuse body 144 and conductive elements or end plates 146, 148. Fuse indicator 140 is coupled to fuse 142 via end plates 146, 148. Fuse indicator 140 is constructed substantially similar to fuse indicator 10 (shown in FIGS. 1-3) except that fuse terminals 140, 142 are configured as clips to facilitate installation of fuse state indicator 140 to the monitored fuse 142. Specifically, and as illustrated in FIG. 5, terminals 150, 152 include a pair of bends and generally linear segments therebetween that allow terminals 150, 152 to flex as indicator 140 is installed into a slot 154 in each of the fuse end plates. As such, fuse state indicator 140 may be rather easily installed and removed from the monitored fuse 142.

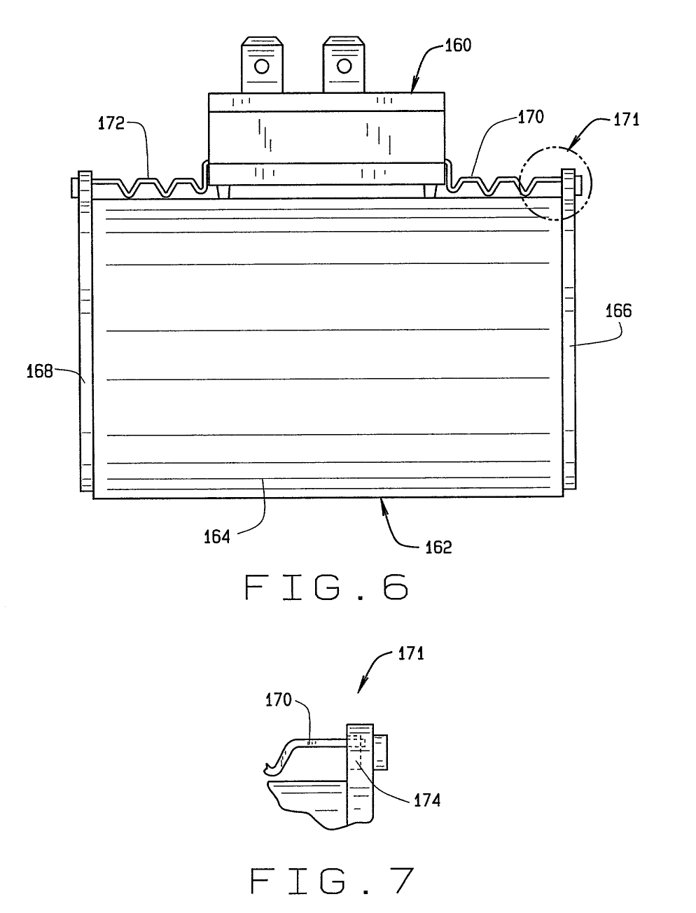

FIGS. 6 and 7 are an elevational view and a detail view of a second embodiment of a magnetic actuated fuse state indicator 160 coupled to a fuse 162. Fuse 162 includes a fuse body 164 and conductive elements or end plates 166, 168. Fuse indicator 160 is coupled to fuse 162 via end plates 166, 168. Fuse indicator 160 is constructed substantially similar to fuse indicator 10 (shown in FIGS. 1-3) except that fuse terminals 170, 172 are configured as clips to facilitate installation of fuse state indicator 160 to the monitored fuse 162. Specifically, and as illustrated in FIGS. 6 and 7, terminals 170, 172 include a plurality of bends and generally linear segments therebetween in a ridge and valley configuration. The configuration of the bends and straight segments allow terminals 170, 172 to flex as indicator 160 is installed into a slot 174 in each of the fuse end plates. As such, fuse state indicator 140, 122 may be rather easily installed and removed from the monitored fuse 162.

It should now be apparent that fuse terminals for the above described fuse state indicators 10, 140, 160 may be varied considerably to suit particular fuses and assembly considerations with clip-on or snap fit engagement.

While the invention has been described in terms of various specific embodiments, those skilled in the art will recognize that the invention can be practiced with modification within the spirit and scope of the claims.

What is claimed is:

1. A fuse state indicator comprising:
a housing;
first and second fuse terminals extending from said housing;
an actuator assembly disposed within said housing; and
a magnetically actuated contact assembly disposed within said housing, said contact assembly responsive to said actuator assembly.

2. A fuse state indicator in accordance with claim 1 wherein said actuator assembly comprises a permanent magnet.

3. A fuse state indicator in accordance with claim 2 wherein said contact assembly comprises a reed contact.

4. A fuse state indicator in accordance with claim 2 further comprising at least one magnetic shunt situated over said contact assembly.

5. A fuse state indicator in accordance with claim 2 further comprising at least one magnetic shunt situated over said actuator assembly.

6. A fuse state indicator in accordance with claim 2 further comprising a bias element engaged to said magnet.

7. A fuse state indicator in accordance with claim 6 wherein said bias element is compressed by said magnet before said indicator has operated.

8. A fuse state indicator in accordance with claim 1 wherein said contact assembly is normally open.

9. A fuse state indicator in accordance with claim 1 wherein said contact assembly is normally closed.

10. A fuse state indicator comprising:
a housing;
first and second fuse terminals extending from said housing;
a fuse wire extending between said first and second fuse terminals;
an actuator arm situated within said housing and coupled to said fuse wire;
a magnet element in abutting relationship with said actuator arm;
a resilient element biasing said magnet element against said actuator arm;
first and second contact terminals situated within said housing; and
a magnetically actuated contact extending between said first and second contact terminals and responsive to a position of said magnet element.

11. A fuse state indicator in accordance with claim 10 further comprising at least one magnetic shunt disposed about said contact.

12. A fuse state indicator in accordance with claim 10 wherein said contact comprises a reed contact.

13. A fuse state indicator in accordance with claim 10 wherein at least one of said first and second fuse terminals comprises a clip.

14. An external fuse state indicator for attachment to a fuse, said indicator comprising:
a housing;
a fuse wire located within said housing and establishing an electrical connection to the fuse;
first and second contact terminals located within said housing;
a contact extending within said housing and configured to complete an electrical connection through said first and second contact terminals;
a permanent magnet disposed in said housing in a first position in spaced apart relationship from said contact, said magnet biased to a second position in spaced apart relationship from said contact when said fuse wire operates, said second position of said magnet effecting a change in orientation of said contact.

15. An external fuse state indicator in accordance with claim 14 wherein said contact is in a normally closed position establishing an electrical circuit through said contact terminals.

16. An external fuse state indicator in accordance with claim 14 wherein said contact is in a normally open position opening an electrical circuit through said contact terminals.

17. A fuse state indicator in accordance with claim 14 wherein said contact comprises a reed contact.

18. A fuse state indicator in accordance with claim 17 further comprising a magnetic shunt covering at least a portion of said reed contact.

19. A fuse system comprising:
a fuse comprising a fuse body and first and second conductive elements coupled to said body; and
a magnetically actuated fuse state indicator externally coupled to said body in electrical contact with said conductive elements.

20. A fuse system in accordance with claim 19, said fuse state indicator comprising a housing and first and second fuse terminals extending from said housing, each said conductive element comprising a slot therein, said fuse terminals received in respective slots of said conductive elements.

21. A fuse system in accordance with claim 20 wherein at least one of said fuse terminals is configured to flex when said indicator is coupled to said fuse.

22. A fuse system in accordance with claim 21, said indicator comprising an actuator housing, a permanent magnet situated within said housing, and a reed contact in a spaced apart relationship from said magnet.
